(19) United States
(12) Patent Application Publication
(10) Pub. No.: US 2025/0142991 A1
(43) Pub. Date: May 1, 2025

(54) OPTICAL PACKAGE COMPRISING A COATING BETWEEN AN OPTICAL ELEMENT AND AN ELECTRONIC CHIP

(71) Applicant: STMICROELECTRONICS INTERNATIONAL N.V., Geneva (CH)

(72) Inventors: Younes BOUTALEB, Grenoble (FR); Julien CUZZOCREA, MONTBONNOT ST MARTIN (FR)

(21) Appl. No.: 18/913,256

(22) Filed: Oct. 11, 2024

(30) Foreign Application Priority Data
Oct. 26, 2023 (FR) 2311632

(51) Int. Cl. H01L 27/146; H01L 23/00; H01L 23/31

(52) U.S. Cl. CPC H10F 39/804; H01L 23/3135; H01L 23/315; H01L 24/32; H01L 24/48; H01L 24/73; H10F 39/024; H10F 39/806; H01L 2224/32225; H01L 2224/48227; H01L 2224/73265

(57) ABSTRACT

The present disclosure provides an optical package. An example optical package includes: a support substrate having a mounting face equipped with first electrically conductive contact pads; an electronic chip comprising a front face including second contact pads electrically connected to the first contact pads by conductive wires; a film on wire type coating that coats a first portion at least of the conductive wires and the second contact pads; and an optical element attached on the coating, the coating delimiting an inner housing between the optical element and the front face of the electronic chip.

### CROSS REFERENCE TO RELATED APPLICATION(S)

This application claims the priority benefit of French Patent Application number 2311632, filed on Oct. 26, 2023, entitled “Boitier Optique Comprenant Un Enrobage Entre Un Élément Optique Et Une Puce Électronique”, which is hereby incorporated by reference to the maximum extent allowable by law.

### TECHNICAL FIELD

Embodiments and implementations relate to the field of integrated circuit packaging, particularly the optoelectronics field, and more particularly the manufacturing of optical devices.

### BACKGROUND

Optical devices such as optical packages conventionally comprise a support substrate whereon at least one electronic chip is mounted that is electrically connected to the support substrate by conductive wires.

In particular, the chip of such a package has an optical component, such as a matrix of pixels for example, on a functional face and electrical contacts connected to electronic circuits, for example circuits that control the emission or the receipt of an optical signal by the optical component.

Furthermore, the substrate also has electrical contacts that are typically connected to the electrical contacts of the chip by means of conductive wires. The connection between the respective electrical contacts of the chip and of the substrate particularly makes it possible to pass electrical signals between the substrate and the electronic circuits of the chip.

During the manufacturing of optical packages, a plurality of chips may be attached and connected on respective locations of the same wafer that is subsequently cut in order to form individualised optical packages, that is to say that each include an electronic chip and a support substrate. At the moment of cutting the wafer, dendrite particles typically spread over the functional face of the chip and consequently may deteriorate the operation of the chip, for example by hindering the emission or the transmission of the optical signal by the optical component of the chip.

In this regard, the optical packages sometimes include walls, formed on the functional face of the chip, for protecting the functional face of the chip, and more particularly the optical matrix from a dendrite deposit.

Moreover, the arrangement of the walls and of the optical element on the support substrate makes it possible to protect the electrical contacts of the support substrate and those of the chip from the dendrite deposit risk.

However, no known arrangements of the walls and of the optical element make it possible to sufficiently protect the electrical contacts and the optical matrix without on the one hand inducing relatively high manufacturing costs, and on the other hand a complex design of the package, for example by using on the one hand an adhesive to attach the optical element and on the other hand a resin to cover the electrical contacts.

Therefore, there is a need to find a solution for preventing the dendrite deposit on the electrical contacts and/or the optical matrix while making the manufacturing of optical packages less expensive and less complex.

### BRIEF SUMMARY

According to one aspect, an optical package is proposed including:
a support substrate having a mounting face equipped with first electrically conductive contact pads,
an electronic chip comprising a rear face attached on the mounting face of the support substrate and a front face including second contact pads electrically connected to the first contact pads by conductive wires.

The optical package also includes a film on wire type coating that coats a first portion at least of the conductive wires and the second contact pads, and an optical element, such as a lens, attached on the coating and being in optical cooperation with the electronic chip, the coating delimiting an inner housing between the optical element and the front face of the electronic chip.

The film on wire type coating typically makes it possible to protect the second contact pads from a dendrite deposit and from the effects of moisture and temperature that may affect the electrical performances of the package.

Furthermore, the coating has the advantage of attaching the optical element on the chip while preventing the inclination of the optical element in relation to the front face of the chip, as opposed to a conventional adhesive that would be used to attach the optical element and the thickness of which is more difficult to control during the deposit than that of the film on wire type coating. Thus, the coating ensures a better base, in particular flatter, for the optical element.

The optical package according to this aspect therefore makes it possible to minimise or even avoid the presence of dendrite in the inner housing thanks to an advantageous arrangement of the coating and of the optical element in terms of ease of production and of cost.

According to one embodiment, the support substrate comprises a cavity housing the electronic chip, the rear face of the chip being attached on the mounting face by an adhesive at a depth of the substrate so that the conductive wires connecting the second contact pads to the first contact pads extend from the mounting face up to a maximum height lower than the thickness of the coating.

Thus, the positioning of the chip in the cavity makes it possible to reduce the distance between the front face of the chip and the mounting face of the substrate, consequently reducing the size and the height of the loop of the conductive wires as well as the distance separating the optical element from the support substrate.

An optical package that has such a cavity is therefore more compact.

According to one embodiment, the thickness of the adhesive is chosen so that the sum of the thickness of the adhesive and the thickness of the chip is equal to the nearest tolerance at the depth.

The wire height of the conductive wires may be limited without however being restrictive for the positioning of the chip that may be slightly raised in relation to the mounting face of the substrate according to a certain tolerance.

According to one embodiment, the coating also coats a second portion of the conductive wires and the first contact pads.

The film on wire type coating consequently makes it possible to simultaneously protect the contact pads of the chip and of the substrate.

Therefore, it is no longer necessary to protect the contact pads of the substrate, which makes it possible to simplify the manufacturing of the optical package and make it more economical.

According to one embodiment, the optical package comprises a glob top that coats a second portion of the conductive wires and the first contact pads.

The glob top makes it possible to protect the second portion of the conductive wires and the contact pads of the substrate in the same way that the film on wire type coating protects the contact pads of the chip.

According to one embodiment, the optical package comprises a moulding resin that coats a second portion of the conductive wires and the first contact pads.

Alternatively, the second portion of the conductive wires and the contact pads of the substrate are protected by a moulding resin typically used for the packaging of packages.

According to one embodiment, the film on wire type coating has a thickness between 30 μm and 100 μm.

The coating having this thickness range makes it possible to attach the optical element while making the optical package more compact. Indeed, the thickness of the coating may be easily controlled during the manufacturing of the package and makes it possible to avoid using an adhesive that may need a greater thickness to make it possible to attach the optical element and that may therefore be restrictive in relation to the dimensions of the package.

According to another aspect, a method for manufacturing an optical package is proposed comprising:
providing a support substrate having a mounting face equipped with first electrically conductive contact pads,
attaching a rear face of an electronic chip on the mounting face of the support substrate,
electrically connecting the second contact pads of a front face of the chip to the first contact pads by conductive wires,
forming a film on wire type coating that coats a first portion at least of the conductive wires and the second contact pads,
attaching an optical element on the coating, the optical element being in optical cooperation with the electronic chip,

the coating delimiting an inner housing between the optical element and the front face of the electronic chip;

According to one implementation, the method comprises forming a cavity in the support substrate housing the electronic chip, wherein the rear face of the chip is attached on the mounting face by an adhesive at a depth of the support substrate so that the conductive wires connecting the second contact pads to the first contact pads extend from the mounting face up to a maximum height lower than the thickness of the coating.

According to one implementation, the thickness of the adhesive is chosen so that the sum of the thickness of the adhesive and the thickness of the chip is equal to the nearest tolerance at the depth.

According to one implementation, the coating also coats a second portion of the conductive wires and the first contact pads.

According to one implementation, the method comprises forming a glob top that coats a second portion of the conductive wires and the first contact pads.

According to one implementation, the method comprises moulding the package by a moulding resin that coats a second portion of the conductive wires and the first contact pads.

According to one implementation, the film on wire type coating has a thickness between 30 μm and 100 μm.

### BRIEF DESCRIPTION OF THE DRAWINGS

Other advantages and features of the present disclosure will become apparent upon examining the detailed description of non-limiting embodiments and implementations, and from the accompanying drawings, wherein:

FIG. 1; FIG. 2; FIG. 3; FIG. 4; FIG. 5; FIG. 6; FIG. 7; FIG. 8; FIG. 9; FIG. 10; FIG. 11; FIG. 12; and FIG. 13 schematically illustrate implementations and embodiments of the present disclosure.

### DETAILED DESCRIPTION

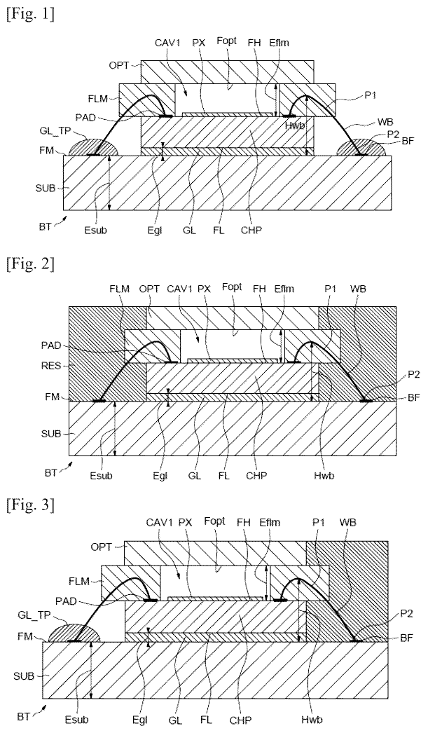

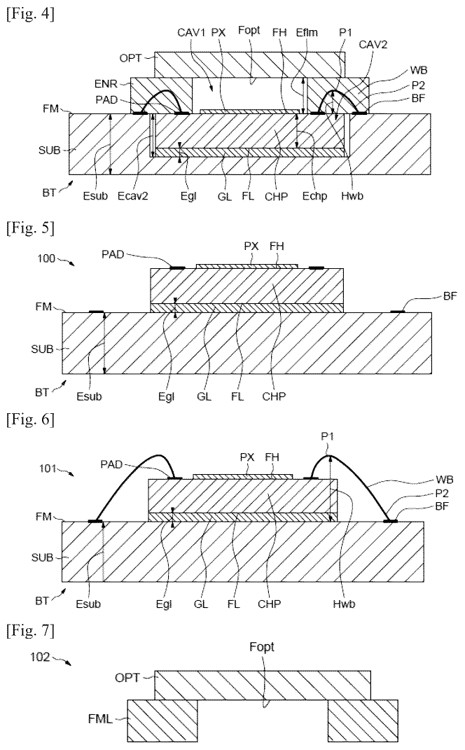

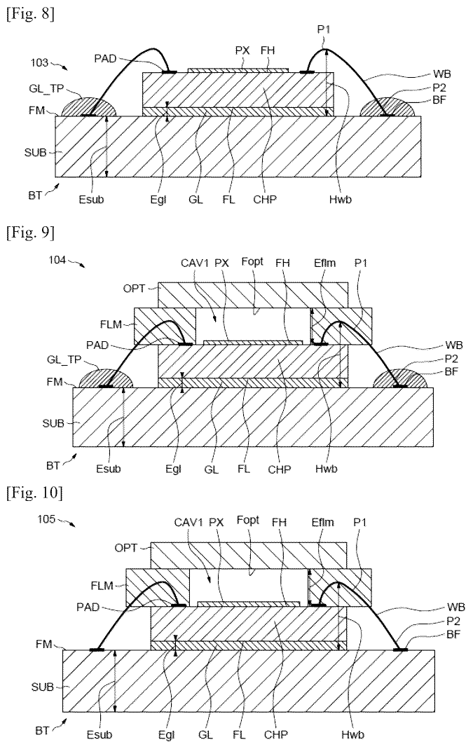

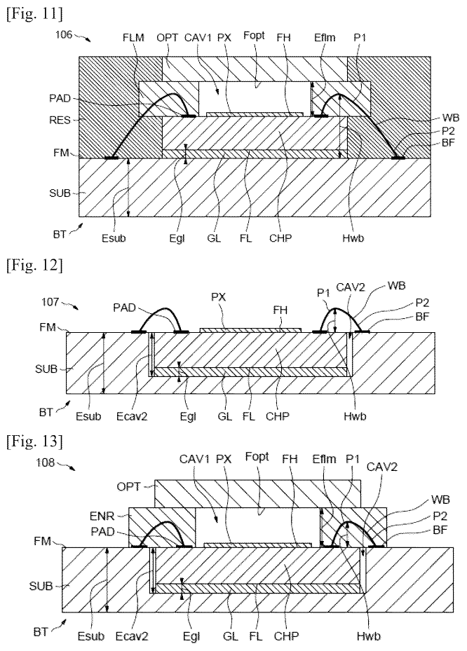

FIG. 1 schematically illustrates a sectional view of an optical package BT according to a first embodiment of the present disclosure.

The package BT includes a support substrate SUB comprising a mounting face FM equipped with first electrically conductive contact pads BF. The first contact pads BF are for example bonding fingers type contacts.

The optical package BT also includes an electronic chip CHP. The electronic chip CHP includes a rear face FL attached on the mounting face FM of the support substrate SUB, for example by means of an adhesive GL. The electronic chip CHP further comprises a front face FH that includes for example an optical component PX such as a matrix of pixels for generating an electrical signal from an optical signal coming from outside of the package BT, then also includes electronic components such as transistors.

Moreover, the front face FH of the chip CHP includes second electrically conductive contact pads PAD, for example of the bonding fingers type or bonding surfaces known by the person skilled in the art. The second pads PAD of the front face FH of the chip CHP are electrically connected to the first contact pads BF by conductive wires WB.

The first pads BF and second contact pads PAD as well as the conductive wires WB make it possible to pass electrical signals between the electrical components of the chip CHP and of the circuits outside of the package BT, for example the electrical signal generated by the matrix of pixels PX.

The optical package BT further comprises a film on wire type coating FLM and an optical element OPT such as a filter or a lens for example. The coating FLM may be for example a coating of reference ESP7666-FOW marketed by AI Technology INC.

The film on wire type coating FLM coats a first portion P1 of the conductive wires WB and the second contact pads PAD. The first portion P1 coated by the coating FLM corresponds for example to the portion of the conductive wires WB extending from the second pads PAD up to a distance defined during the formation of the coating FLM.

The optical element OPT is attached on the coating FLM and is in optical cooperation with the electronic chip CHP. The optical element OPT is for example superposed on the optical component PX of the chip CHP and makes it possible to perform optical functions (filtering, biasing for example) on the optical radiation received or emitted by the optical component PX.

The coating FLM delimits an inner housing CAV1 between the optical element OPT and the front face FH of the electronic chip CHP, wherein the optical component PX is located as well as the electronic components of the chip CHP.

The film on wire type coating FLM therefore makes it possible to prevent the dendrite deposit during the manufacturing of the package BT on the second contact pads PAD as well as on the elements located in the inner housing and particularly makes it possible to protect the contact pads PAD from the effects of moisture and temperature that may affect the electrical performances of the package BT.

Furthermore, the coating FLM has the advantage of attaching the optical element OPT on the chip CHP while preventing the inclination of the optical element OPT in relation to the front face FH, as opposed to a conventional adhesive that would be used to attach the optical element and the thickness of which is more difficult to control during the deposit than that of the film on wire type coating. Thus, the coating FLM ensures a better base, in particular flatter, for the optical element OPT.

Such an arrangement of the coating and of the optical element makes it possible for the optical package BT to be easier to manufacture while making it less expensive.

Moreover, the coating FLM has a thickness Eflm between 30 μm and 100 μm

The coating FLM having this thickness range makes it possible to attach the optical element while making the optical package more compact. Indeed, the thickness Eflm of the coating FLM may be easily controlled and makes it possible to avoid using an adhesive that may need a greater thickness to make it possible to attach the optical element and that may therefore be restrictive in relation to the dimensions of the package BT.

The optical package BT also comprises a glob top GL_TP, which coats a second portion P2 of the conductive wires WB and the first contact pads BF. The second portion P2 coated by the glob top GL_TP corresponds for example to the portion of the conductive wires WB extending from the first pads BF up to a distance defined during the formation of the glob top GL_TP.

The glob top GL_TP makes it possible to protect the second portion P2 of the conductive wires and the contact pads BF of the substrate SUB from the effects of moisture and temperature.

FIG. 2 schematically illustrates a sectional view of an optical package BT according to a second embodiment. The elements in common with the package BT in FIG. 1 have the same references and will not all be detailed again.

The package BT comprises a moulding resin RES, such as the resin typically used for the packaging of packages. The moulding resin RES coats the second portion P2 of the conductive wires WB and the first contact pads BF.

Thus, the resin RES makes it possible to protect the second portion P2 of the conductive wires WB and the first contact pads BF as well as the other elements of the package BT such as the optical element OPT.

FIG. 3 schematically illustrates a sectional view of an optical package BT according to a third embodiment. The elements in common with the package BT in FIG. 1 have the same references and will not all be detailed again.

The package BT includes both the glob top GB_TP of the first embodiment that coats one or more contact pads BF of the substrate and the second portion P2 of the conductive wires WB connected to these contact pads BF, then the moulding resin RES of the second embodiment that coats the contact pads BF and the second portion P2 of the conductive wires WB not coated by the glob top GB_TP.

FIG. 4 schematically illustrates a sectional view of an optical package BT according to a fourth embodiment. The elements in common with the package BT in FIG. 1 have the same references and will not all be detailed again.

The support substrate SUB comprises a cavity CAV2 that houses the electronic chip CHP. The rear face FL of the chip CHP is attached on the mounting face FM at a depth Ecav2 of the substrate SUB so that the conductive wires WB extend from the mounting face FM up to a maximum height Hwb lower than the thickness Eflm of the coating FLM.

In particular, the depth Ecav2 is between 30 and 70% of the thickness Esub of the support substrate SUB.

Indeed, the conductive wires WB that connect the first contact pads BF and the second contact pads PAD have a maximum height that corresponds to the height of the loop formed by the conductive wires WB. As an indication, this maximum height may be between 40 and 70% of the thickness of the film on wire type coating FLM.

Thus, the positioning of the chip CHP in the cavity CAV2 makes it possible to reduce the distance between the front face FH of the chip CHP and the mounting face FM of the substrate SUB, consequently reducing the size and the height of the loop of the conductive wires WB as well as the distance separating the optical element OPT from the support substrate SUB.

An optical package BT that has such a cavity is therefore more compact.

The adhesive GL has a thickness Egl that may be adapted depending on the depth Ecav2 of the cavity CAV2 and thus makes it possible to adjust the positioning of the chip CHP in the cavity CAV2.

Advantageously, the thickness of the adhesive GL is chosen so that the sum of the thickness Egl of the adhesive and the thickness Echp of the chip is equal to the nearest tolerance at the depth Ecav2.

The loop height of the conductive wires WB may be limited without however being restrictive for the positioning of the chip CHP that may be slightly raised in relation to the mounting face FM of the substrate SUB according to a certain tolerance.

For example, the tolerance may correspond to a maximum difference of approximately 10 μm between the front face FH of the chip CHP and the mounting face FM of the substrate SUB below which the formation of the coating FLM is not hindered by the chip CHP during the manufacturing of the package BT.

The coating FLM also coats the second portion P2 of the conductive wires WB and the first contact pads BF.

The film on wire type coating FLM consequently makes it possible to simultaneously protect the contact pads of the chip CHP and of the substrate SUB.

Therefore, it is no longer necessary to protect the contact pads BF of the substrate SUB by the glob top as described above in relation with FIG. 2 or by the moulding resin as described above in relation with FIG. 3, which makes it possible to simplify the manufacturing of the optical package and make it more economical.

FIGS. 5 to 9 schematically illustrate a method for manufacturing optical devices according to a first implementation. Such a manufacturing method is used, for example, to manufacture an optical package BT, as shown in FIG. 1.

FIG. 5 illustrates a step 100 of providing a support substrate SUB. In particular, the substrate SUB includes a mounting face FM of the substrate SUB equipped with first electrically conductive contact pads BF.

Step 100 also comprises attaching a rear face FL of an electronic chip CHP on the mounting face FM of the support substrate SUB. The attachment of the rear face FL may be performed by means of an adhesive GL for example.

Furthermore, the electronic chip CHP comprises a front face FH opposite the rear face FL. The front face FH of the chip CHP comprises second electrically conductive contact pads PAD. The front face FH of the chip CHP also includes an optical component such as a matrix of pixels PX as well as electronic components such as transistors.

FIG. 6 illustrates a step 101 of connecting the front face FH of the chip CHP to the mounting face FM of the support substrate SUB.

More particularly, the connection of step 101 is an electrical connection of the second contact pads PAD of the front face FH of the chip CHP to the first contact pads BF by conductive wires WB thanks to a wire bonding type mounting.

The conductive wires WB typically extend from the mounting face FM up to a maximum height Hwb corresponding to the height of the loop formed by the conductive wires WB.

FIG. 7 illustrates a step 102 of forming a film on wire type coating FLM.

The coating FLM is formed on a face Fopt of an optical element OPT such as a filter or a lens. The coating FLM may be for example a coating of reference ESP7666-FOW marketed by AI Technology INC and has a thickness Eflm between 30 μm and 100 μm.

Such a coating FLM is typically envisaged to cover a first portion P1 of the conductive wires WB as described hereinafter in relation with FIG. 9.

Alternatively (not shown), the coating FLM is formed on the front face FH of the chip CHP so as to coat the first portion P1 at least of the conductive wires WB and the second contact pads PAD before attaching the optical element OPT on the coating FLM.

FIG. 8 illustrates a step 103 of forming a glob top GL_TP.

The glob top GL_TP coats a second portion P2 of the conductive wires WB and the first contact pads BF.

FIG. 9 illustrates a step 104 of attaching the coating FLM on the front face FH of the chip CHP.

More particularly, the coating FLM coats the first portion P1 of the conductive wires WB and the second contact pads PAD while making it possible for the optical element OPT to be in optical cooperation with the electronic chip CHP. Indeed, the optical element OPT may be positioned facing the optical component PX of the chip CHP so that the optical element OPT is passed through by the optical signal received by the optical component PX of the chip CHP.

Furthermore, the coating FLM delimits an inner housing CAV1 between the optical element OPT and the front face FH of the electronic chip CHP.

FIGS. 10 and 11 schematically illustrate steps 105 and 106 of the method for manufacturing the optical package BT according to a second implementation. More particularly, steps 105 and 106 are performed from steps 100 to 102 described above in relation with FIGS. 5 to 7. The method according to this second implementation is for example used to manufacture an optical package BT, as shown in FIG. 2.

FIG. 10 more particularly illustrates a step 105 of attaching the coating FLM on the front face FH of the chip CHP.

During step 105, the coating FLM is attached on the front face FH in a similar way to the coating FLM during step 104 described above in relation with FIG. 9.

On the other hand, at this stage, the first contact pads BF as well as the second portion P2 of the conductive wires WB are not coated by the glob top.

FIG. 11 schematically illustrates a step 106 of moulding the package BT.

The moulding of the package BT is performed by a moulding resin RES that coats the second portion P2 of the conductive wires WB as well as the first contact pads BF.

Thus, the second portion of the conductive wires WB and the first contact pads BF are protected during a moulding that is typically carried out during the manufacturing of packages to ensure the protection of the various elements of the package such as the support substrate SUB and the optical element OPT.

Alternatively, the moulding of step 106 is carried out after a step of forming a glob top GL_TP, such as step 103 described above in relation with FIG. 8.

In this way, it is possible to coat one or more contact pads BF of the substrate and the second portion P2 of the conductive wires WB connected to these contact pads BF by the glob top GB_TP and to coat by the moulding resin RES the contact pads BF and the second portion P2 of the conductive wires WB not coated by the glob top GB_TP. Thus, the method according to this alternative embodiment makes it possible to obtain an optical package BT such as the package illustrated in FIG. 3.

FIGS. 12 and 13 schematically illustrate steps 107 and 108 of the method for manufacturing the optical package BT according to a third implementation. The method according to this third implementation is for example used to manufacture an optical package BT, as shown in FIG. 4.

FIG. 12 schematically illustrates a step 107 of attaching the electronic chip CHP and connecting the front face FH of the chip CHP to the mounting face FM of the support substrate SUB.

In particular, step 107 is preceded by a step (not shown) of forming a cavity CAV2 in the support substrate SUB.

The cavity CAV2 is typically adapted to house the electronic chip CHP. The rear face FL of the chip CHP is attached on the mounting face FM at a depth Ecav2 of the substrate SUB.

As an indication, the depth Ecav2 is between 30 and 70% of the thickness Esub of the support substrate SUB.

During step 107, the second contact pads PAD of the front face FH of the chip are electrically connected to the first contact pads BF in a similar way to the connection of the second contact pads of step 103 described above in relation with FIG. 8.

FIG. 13 schematically illustrates a step 108 of attaching the coating FLM on the front face FH of the chip CHP. Step 108 is performed from step 102 of forming the coating FLM as described above in relation with FIG. 7.

The coating FLM not only coats the first portion P1 of the conductive wires and the second contact pads PAD, but also the second portion P2 of the conductive wires WB and the first contact pads BF.

In particular, the conductive wires WB that connect the second contact pads PAD to the first contact pads BF extend from the mounting face FM up to a maximum height Hwb lower than the thickness Eflm of the coating FLM.

As an indication, the maximum height Ewb is between 40 and 70% of the thickness of the film on wire type coating FLM.

Advantageously, the thickness of the adhesive GL is chosen so that the sum of the thickness Egl of the adhesive and the thickness Echp of the chip is equal to the nearest tolerance at the depth Ecav2.

1. An optical package comprising:
a support substrate having a mounting face equipped with first electrically conductive contact pads;
an electronic chip comprising a rear face attached on the mounting face of the support substrate and a front face including a plurality of second contact pads electrically connected to the first contact pads by conductive wires;
a film on wire type coating that coats a first portion at least of the conductive wires and the second contact pads; and
an optical element attached on the coating and being in optical cooperation with the electronic chip, wherein the coating delimits an inner housing between the optical element and the front face of the electronic chip.

2. The optical package of claim 1, wherein the support substrate comprises a cavity housing the electronic chip, the rear face of the chip being attached on the mounting face by an adhesive at a depth of the substrate so that the conductive wires connecting the second contact pads to the first contact pads extend from the mounting face up to a maximum height lower than a thickness of the coating.

3. The optical package of claim 2, wherein the thickness of the adhesive is chosen so that a sum of the thickness of the adhesive and the thickness of the chip is equal to a nearest tolerance at the depth.

4. The optical package of claim 1, wherein the coating also coats a second portion of the conductive wires and the first contact pads.

5. The optical package of claim 1, comprising a glob top that coats a second portion of the conductive wires and the first contact pads.

6. The optical package of claim 1, comprising a moulding resin that coats a second portion of the conductive wires and the first contact pads.

7. The optical package of claim 1, wherein the film on wire type coating has a thickness between 30 μm and 100 μm.

8. A method for manufacturing an optical package comprising:
providing a support substrate having a mounting face equipped with first electrically conductive contact pads;
attaching a rear face of an electronic chip on the mounting face of the support substrate;
electrically connecting a plurality of second contact pads of a front face of the chip to the first contact pads by conductive wires;
forming a film on wire type coating that coats a first portion at least of the conductive wires and the second contact pads; and
attaching an optical element on the coating, the optical element being in optical cooperation with the electronic chip, wherein the coating delimits an inner housing between the optical element and the front face of the electronic chip.

9. The method of claim 8 further comprising:
forming a cavity in the support substrate housing the electronic chip, wherein the rear face of the chip is attached on the mounting face by an adhesive at a depth of the support substrate so that the conductive wires connecting the second contact pads to the first contact pads extend from the mounting face up to a maximum height lower than a thickness of the coating.

10. The method of claim 9, wherein a thickness of the adhesive is chosen so that a sum of the thickness of the adhesive and a thickness of the chip is equal to a nearest tolerance at the depth.

11. The method of claim 9, wherein the coating also coats a second portion of the conductive wires and the first contact pads.

12. The method of claim 9 fur comprising comprising forming a glob top that coats a second portion of the conductive wires and the first contact pads.

13. The method of claim 9 further comprising moulding the package by a moulding resin that coats a second portion of the conductive wires and the first contact pads.

14. The method of claim 8, wherein the film on wire type coating has a thickness between 30 μm and 100 μm.
